(19) United States
(12) Patent Application Publication
(10) Pub. No.: US 2012/0161105 A1
(43) Pub. Date: Jun. 28, 2012

(54) UNIAXIALLY STRAINED QUANTUM WELL DEVICE AND METHOD OF MAKING SAME

(76) Inventors: Willy Rachmady, Beaverton, OR (US); Ravi Pillarisetty, Portland, OR (US); Van H. Le, Beaverton, OR (US)

(21) Appl. No.: 12/976,126

(22) Filed: Dec. 22, 2010

(51) Int. Cl. H01L 29/161; H01L 21/336; B82Y 99/00

(52) U.S. Cl. 257/19; 438/285; 257/E21.409; 257/E29.072; 977/755

(57) ABSTRACT

A planar or non-planar quantum well device and a method of forming the quantum well device. The device includes: a buffer region comprising a large band gap material; a uniaxially strained quantum well channel region on the buffer region; an upper barrier region comprising a large band gap material on the quantum well channel region; a gate dielectric on the quantum well channel region; a gate electrode on the gate dielectric; and recessed source and drain regions at respective sides of the gate electrode, the source and drain regions including a junction material having a lattice constant different from a lattice constant of a material of the buffer region. Preferably, the buffer region comprises a Si₁₋ₓGeₓ material, and the junction material comprises one of a Si_{1-y}Ge_{y} material where y is larger than x, or pure germanium, or tin germanium.

### BACKGROUND

Quantum well transistors based on non-silicon materials may provide superior device performance. However, for some quantum-well devices, loss of short channel performance has been attributed to loss of strain due to etch/implant damage in the source and drain regions. Improved processes and structures are needed that solve the above disadvantage.

### BRIEF DESCRIPTION OF THE DRAWINGS

FIG. 1 is a cross sectional side view that illustrates a quantum well channel device prior to formation of the source and drain regions;

FIG. 2 is a view similar to FIG. 1 showing the device of FIG. 1 after formation of source and drain recesses;

FIG. 3 is a view similar to FIG. 1 or 2 showing the device of FIG. 2 after provision of source and drain regions in the recesses;

FIG. 4 is a flow diagram showing a method embodiment; and

FIG. 5 is a schematic depiction of a system including a device according to an embodiment.

### DETAILED DESCRIPTION

In various embodiments, a germanium channel quantum well semiconductor device and its fabrication are described. In the following description, various embodiments will be described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment that falls within the scope of the invention, but do not denote that they are necessarily present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order, in series or in parallel, than the described embodiment. Various additional operations may be performed and/or described operations may be omitted in additional embodiments.

Increased performance in circuit devices on a substrate (e.g., integrated circuit (IC) transistors, resistors, capacitors, etc. on a semiconductor (e.g., silicon) substrate) is typically a major factor considered during design, manufacture, and operation of those devices. For example, during design and manufacture or forming of metal oxide semiconductor (MOS) transistor devices, such as those used in a complementary metal oxide semiconductor (CMOS), it is often favored to increase movement of electrons in N-type MOS device (n-MOS) channels and to increase movement of positive charged holes in P-type MOS device (p-MOS) channels. A key parameter in assessing device performance is the current delivered at a given design voltage. This parameter is commonly referred to as transistor drive current or saturation current (IDsat). Drive current is affected by factors that include the transistor's channel mobility and external resistance. Thus, device performance is affected by channel mobility (e.g., carrier mobility in the channel between the source and drains); and the external resistance (Rext) (e.g., the external resistance seen between a contact to the source and a contact to the drain).

The mobility of carriers (i.e. holes and electrons) in the transistor's channel region may be affected by the channel material composition, doping, and strain (e.g. tensile or compressive strain). Increased carrier mobility translates directly into increased drive current at a given design voltage and gate length. Carrier mobility can be increased by straining the channel region's lattice. For p-MOS devices, carrier mobility (i.e. hole mobility) is enhanced by generating a compressive strain in the transistor's channel region. For n-MOS devices, carrier mobility (i.e. electron mobility) is enhanced by generating a tensile strain in the transistor's channel region.

Rext may be affected by channel material composition, doping, and strain. Rext may also be affected by source and drain material composition and doping; source and drain contact composition and doping; and interfaces between source and drain contacts and the source and drain material. External resistance may be referred to as the sum of: (1) the resistances associated with the ohmic contacts (metal to semiconductor and semiconductor to metal), (2) the resistance within the source and drain region itself, (3) the resistance of the region between the channel region and the source and drain regions (i.e. the tip region), and (4) the interface resistance due to impurity (carbon, nitrogen, oxygen) contamination at the location of the initial substrate-epi-layer interface.

Embodiments pertain to devices that use a “quantum well” (QW), such as a QW between a source and drain. A quantum well is a concept that includes design of a channel “stack” to confine an energy region for carriers that participate in transport, for a MOSFET device. Here the confined energy region (e.g. a layer) is a region with a lower bandgap that is confined between a top layer and a bottom region, each having a higher bandgap. For example, according to embodiments, a quantum well may include a layer of germanium (Ge) or a layer of silicon germanium (SiGe). Alternatively, the quantum well may include a layer of indium gallium arsenide (InGaAs) between a top layer of indium phosphide (InP), and a bottom region of indium aluminum arsenide (InAlAs). Embodiments however are not limited to the above combination of materials for the QW and for the top and bottom barrier layer, but include within their scope QW devices involving Group IV heterostructures, Group III-V heterostructures or Group II hereostructures, by way of example. In each case, the top layer may be described as a “buffer” and/or top “barrier” layer to provide confinement of carriers in “channel” layer and also minimize scattering effect of defects in gate stack on the carrier mobility in the channel (e.g., for a buried channel structure). Also, the bottom region may be described as a bottom “buffer” layer such as to provide confinement of carriers in “channel” layer (like the top layer) and also improve the electrostatic integrity by insulating the channel from the bulk (e.g., for a SOI like scheme).

Below the bottom region may be a substrate. The substrate may be a bulk style substrate or a silicon-on-insulator (SOI) substrate. The substrate may include a graded buffer below the QW bottom buffer. Below the graded buffer may be another buffer region or a substrate layer, such as a silicon handle wafer. Alternatively, below the bottom barrier may be an insulator layer, and then a substrate, such as to form a silicon-on-insulator (SOI) or heterostructure-on-insulator (HOI) structure. Generally, layers below the QW bottom buffer region may be described as the substrate, or as part of the substrate.

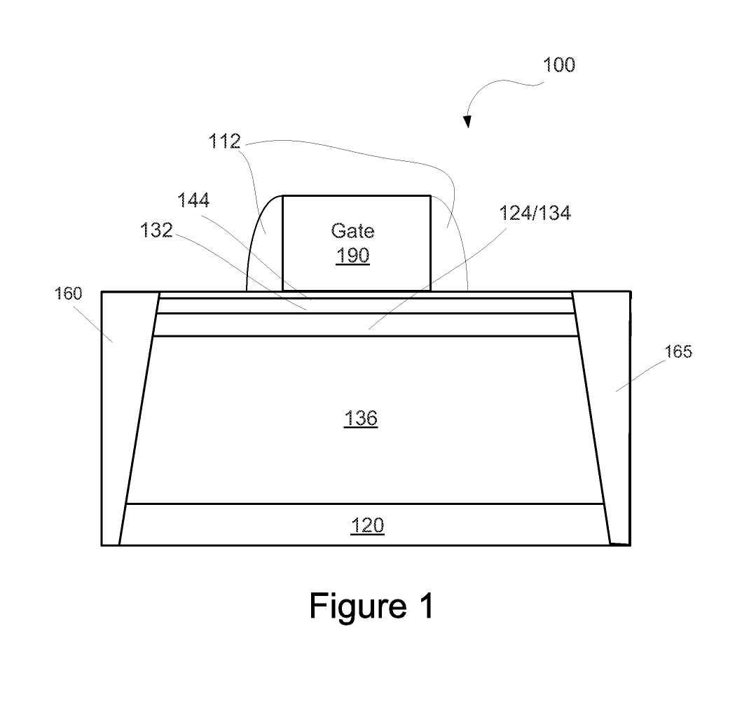

According to some embodiments described with respect to FIGS. 1-3, locally straining transistor quantum well (QW) channel regions may be accomplished by the provision of epitaxially grown source and drains in recessed regions extending down into the bottom buffer region, where the material of the source and drain regions have a different lattice spacing that a lattice spacing of the bottom buffer region. Providing source and drain recesses that extend deep into the bottom buffer region and filling those recesses with a material that presents a lattice spacing differential with that of the material of the bottom buffer may impart a uniaxial strain to the QW channel, in this way advantageously improving device performance.

FIG. 1 is a schematic cross-sectional view of a portion of a substrate having a quantum well, gate dielectric, and gate electrode. FIG. 1 shows apparatus 100 including substrate 120 having gate dielectric 144 formed on top surface 125 of substrate quantum well (QW) 124. Gate electrode 190 is formed on gate dielectric 144. QW 124 includes top barrier or buffer region 132 that is or that includes a barrier material formed on or touching channel region 134. Channel region 134 is or includes a channel material formed on or touching buffer region 136. Buffer region 136 is made of or includes a buffer material. Buffer region 136 may be formed on or be touching substrate 120. Gate dielectric 144 may be formed on or touching layer 132. Surface 170 of layer 132 is shown extending under gate electrode 190. Apparatus 100, and components thereof described above may be further processed, such as in a semiconductor transistor fabrication process that involves one or more processing chambers, to become or be parts of a QW p-MOS transistor (e.g., by being parts of a CMOS device). According to embodiments, bottom buffer region 136 may for example comprise a Si₁₋ₓGeₓ alloy material. As noted above, however, embodiments are not limited to the provision of a Ge based device, and include within their scope for example a Group IV, Group III-V or Group II-VI heterostructure where for example the bottom buffer region is a composite material within the stated material Groups.

As shown in FIG. 1, substrate 120 includes a QW 124 thereon. Quantum well 124 includes a channel region 134 to confine an energy region for carriers that participate in transport, for a MOSFET device. Here the confined energy region (e.g. the channel) is a region with a lower bandgap that is confined between top barrier region and bottom buffer region, each having a higher bandgap. For example, a quantum well may include layer 134 of germanium (Ge) or silicon germanium (SiGe). It can be appreciated that layer 134 may include various materials suitable for forming a QW “channel” of a transistor device. A transistor device QW channel may be defined as a portion of the channel material of QW 124 under top or layer 132 above layer 136, and between surfaces of junctions formed adjacent to electrode 190. Specifically, a source and a drain may be formed adjacent to QW 124, so that QW 124 is a quantum well between the source and drain. The source and drain may each be a junction region, such as an opening formed adjacent to a quantum well (e.g., through a channel region), and then filled with junction material.

Gate electrode 190 may be formed by processes described above with respect to forming gate dielectric 144. Gate dielectric 144 may be formed of a material having a relatively high dielectric constant (e.g., a dielectric constant greater than or equal to that of silicon dioxide (SiO.sub.2)), of a material having a relatively low dielectric constant, and may include various suitable materials as know in the art for gate electrics over quantum wells. Gate dielectric 144 may be formed by deposition, such as by CVD, atomic layer deposition (ALD), blanket deposition, and/or other appropriate growing, depositing, or forming processes. Gate electrode 190 may have an appropriate work function for a MOS device. Moreover, gate electrode 190 may be formed of various semiconductor or conductor materials, such as silicon, polysilicon, crystal silicon, and/or various other appropriate gate electrode materials. For example, the gate electrode may be made of a metal, such as, for example, tantalum, tungsten, tantalum nitride, and titanium nitride. Where a metal gate is used, preferably, it is used in conjunction with a high-k dielectric for the gate dielectric material. Also, gate electrode 190 may be doped during or after formation to form a p-type gate electrode or to form an n-type gate electrode. In some cases, gate electrode 190 may be formed of TaN/HfSiOx (oxide), or other suitable gate electrode materials as know in the art for quantum wells.

QW 124 may be an N-type well or a P-type well formed for example by doping in a well-known manner. Doping as described herein may be performed, for example, by angled doping, or by selective doping, such as by placing a mask over the non-selected area or areas to block the introduction of the dopant from entering the non-selected are or areas, while allowing the dopant to dope QW 124 (e.g., doping the channel region). Similarly, the junction regions may be P-type junction regions or N-type junction regions. Spacers 112 on sides of the gate electrode 190 are also shown, and may include a dielectric, such as silicon nitride (Si.sub.3N.sub.4), silicon dioxide (SiO.sub.2), and/or various other appropriate semiconductor device spacer materials. Shallow trench isolation regions 160 and 165 are also shown.

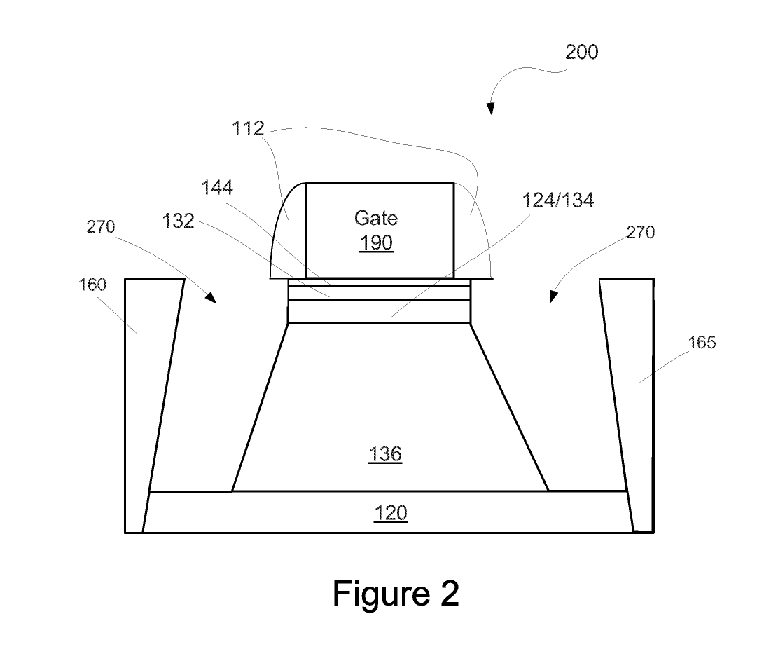

Turning now to FIG. 2, according to embodiments, junction or source and drain openings or recesses 270 may be formed adjacent to gate electrode 190, for example in a self-aligned manner using lithographic processes, to arrive at the device structure 200 shown. Source and drain recesses 270 may be formed by etching through the QW 124 and into the buffer region 136 as suggested in FIG. 2. According to some embodiments, defining recesses 270 may include using for example a wet etch, a dry etch, any combination of a wet etch or a dry etch. For example, it may include using a dry etch followed by a wet etch. According to one embodiment, the wet etch may utilize NH.sub.4OH that is substantially selective to the {111} facet of the buffer region 136. Said alternatively, the wet etch of an embodiment may preferentially etch the buffer region 136 based on crystallographic direction, and in particular etches the buffer region 136 much more slowly along the {111} plane to form a {111} facet as the etch proceeds much more rapidly in other crystallographic directions. Additional wet etch chemistries include NH.sub.3OH, TMAH, KOH, NaOH, BTMH, or an amine-based etchant, each of which in an embodiment has a pH approximately greater than 9.0. In an embodiment for which the wet etch is performed with an amine-based etchant, the amine-based etchant is diluted with deionized water. The diluted amine-based etchant solution of an embodiment is approximately 1.0 to 30.0 weight percent amine-based etchant in deionized water at a temperature of approximately between 24.degree. C. and 90.degree. C. In an embodiment, a 2.5 weight percent NH.sub.4OH solution with deionized water at approximately 24.degree. C. etches source 600 and drain 601 regions to an approximately 170 nanometer undercut depth in an approximately 60 second dip.

In an embodiment, the wet etch of an embodiment to form the source and drain recesses 270 may be preceded by a hydrofluoric acid (HF) dip to remove any native oxide that may exist on the surfaces of the buffer region 136 to be etched. In an embodiment, the native oxide is removed by a dilute hydrofluoric acid with an approximate 1:50 to 1:400 ratio with deionized water at approximately room temperature (e.g., approximately 24.degree. C.). In an embodiment, the native oxide is removed by any buffered oxide etch chemistry targeted to remove approximately 20 angstroms to 30 angstroms of thermal silicon oxide. The wet etch of an embodiment may further be followed by a rinse. In an embodiment, the rinse is a fast upflow deionized water rinse with a flow rate of approximately between 30 and 35 liters per minute. The rinse of an embodiment follows the wet etch of an embodiment quickly to control the wet etch. In an embodiment, the transfer time between the wet etch and the rinse is approximately between 5.0 and 8.0 seconds. Where a wet etch is used to provide recesses 270, the gate 190 of the transistor may be defined by a material that is resistant to the wet etch chemistry. Further, the wet etch chemistry may be selective to the material of the gate dielectric so that it substantially does not etch the same. A mask (not shown) may be provided above the gate electrode in order to protect the same during the wet etch. Where the wet etch is preceded by a dry etch to provide source and drain recesses 270, for example, an etchant gas may be used for the dry etch that may contain mixtures including: chlorine (Cl.sub.2), hydrochloric acid (HCl), hydrogen (H.sub.2), and/or nitrogen (N.sub.2). It can be appreciated that other suitable dry etchants, for anisotropic dry etching the quantum well channel material, may be used. In the case of an initial dry etch, the dry etch may for example etch the barrier region 132, and the wet etchant may etch through the opening created by the dry etchant to form junction recesses 270. The etch of the source drain recesses may be effected for example in a self-aligned manner by aligning the source and drain recess etch to the gate electrode stack and spacers of the multi-gate device.

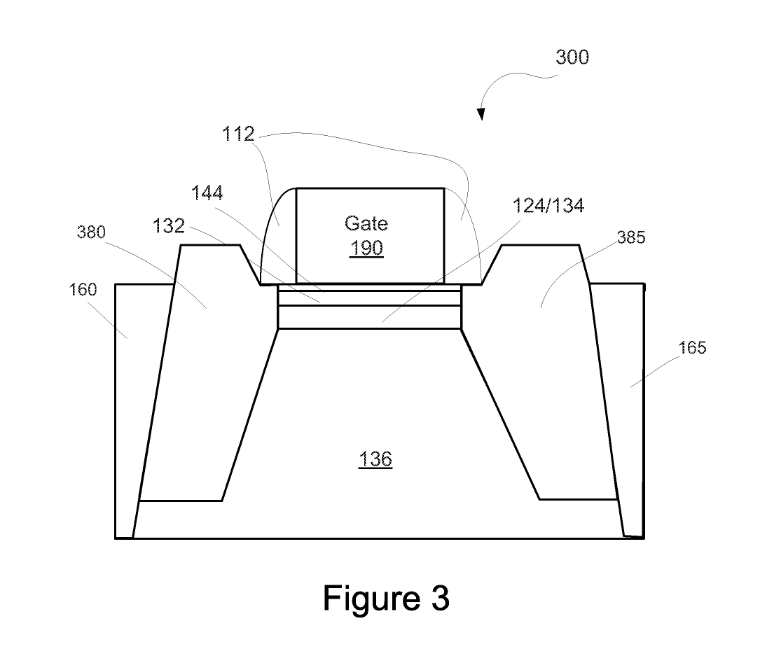

FIG. 3 shows the substrate of FIG. 2 after forming the source and drain regions 380 and 385 to arrive at device structure 300 as shown. According to embodiments, the source and drain regions 380 and 385 may be provided by epitaxially growing the source and drain material, such as, for example, a SiGe alloy into recesses 270. It is understood however that embodiments include within their scope the provision of any material into the source and drain recesses 270 that would present a lattice mismatch with respect to a material of the bottom buffer region in order to impart a strain, whether compressive or tensile, to the channel region. The thus provided epitaxially grown film may comprise a material having a lattice constant different than that of the material of the buffer region 136, such as, for example, a SiGe having a Ge concentration that is different from that of an underlying SiGe buffer. The epitaxially grown film may also include pure Ge, or an SnGe alloy. The material for the source and drain regions may for example include a doped material. For example, the source and drain junction material may be doped while being grown, or it may be filled with the junction material that is subsequently doped. The silicon germanium of the source and drain regions 380 and 385 could for example be doped with boron or aluminum in order to impart a p-type doping to the same, or for example with arsenic, phosphorus or antimony in order to impart a n-type doping to the same.

The source and drain regions 380 and 385 may according to one embodiment extend below a bottom surface of the QW layer to a recess depth between about just below the bottom surface of the QW layer to about 2000 Angstroms below the bottom surface of the QW layer. Preferably, the recess depth is from about 300 Angstroms to about 400 Angstroms below a bottom surface of the QW layer. As suggested in FIG. 3, the source and drain regions 380 and 385 may further comprise raised source and drain regions According to one embodiment, the recessed source and drain regions may extend above a top surface of the QW layer to a source and drain height between about 0 up to about 1500 Angstroms. Preferably, the source and drain height is about 400 Angstroms above the top surface of the QW layer. According to embodiments, the undercut portion of the source and drain regions 380 and 385 may have a lateral depth anywhere from being flush with the outer edge of spacers 112 (that is, the edge of the spacers 112 furthest from the gate electrode 190) to extending under the spacer 112 toward the gate electrode to a lateral depth of about 20 nm. Preferably, the lateral depth of the undercut portions is about 5 nm. Source and drain regions 380 and 385 thus formed may impart a compressive or tensile uniaxial strain to a MOS transistor's QW channel region, in addition for example to a bi-axial strain caused in the channel region by a top barrier region and a bottom buffer region of the quantum well. Materials may be selected for the source and drain regions and for the buffer region to ensure that the lattice spacing of the source and drain regions is different from that of the buffer region. In this way a uniaxial strain may be imparted to QW 124 to enhance channel mobility and to reduce Rext (as compared to without the uniaxial strain) as described herein. The percent different in lattice spacing between the material of the source and drain regions and that of the bottom buffer region may be anywhere from just above 0% to about 5%, and preferably from 1.5% to about 2%. In some embodiments, the material of the source and drain regions may be graded according to application needs. Such grading may for example be achieved using multiple differing epitaxial layers to fill the source and drain recesses 270, each layer presenting a different lattice constant from the previous layer.

According to one embodiment, source and drain regions 380 and 385 may be thermally treated by heating, annealing, and/or flash annealing material with sufficient temperature to cause them to form a sufficient volume of an alloy with the channel material at an interface (e.g., a junction or border) between the channel material to cause a uniaxial strain in channel 134 to increase (or enhance) channel mobility and to reduce Rext (as compared to without the uniaxial strain). The source and drain regions will have a different lattice spacing than the material of the buffer region 136, sufficient to increase channel mobility the device. Thus, the material in source and drain regions 380 and 385 may have a lattice spacing and volume that is larger than or smaller than that of the material of buffer region 136 and cause a compressive or tensile uniaxial strain in channel 134. It can further be appreciated that other suitable materials sufficient to cause a bi-axial compressive strain in a quantum well channels, may also be used for the channel material, the top barrier material, and/or bottom buffer material.

Apparatus 300 may be subsequently processed to form contacts to source and drain regions 380 and 385. For example, apparatus 300 may be processed to be part of a CMOS device in a device layer of an integrated circuit.

It is noted that, although an embodiment has been described above with respect to a planar device, embodiments include within their scope the provision of source and drain regions as described in a non-planar device, such as a double-gate or tri-gate device.

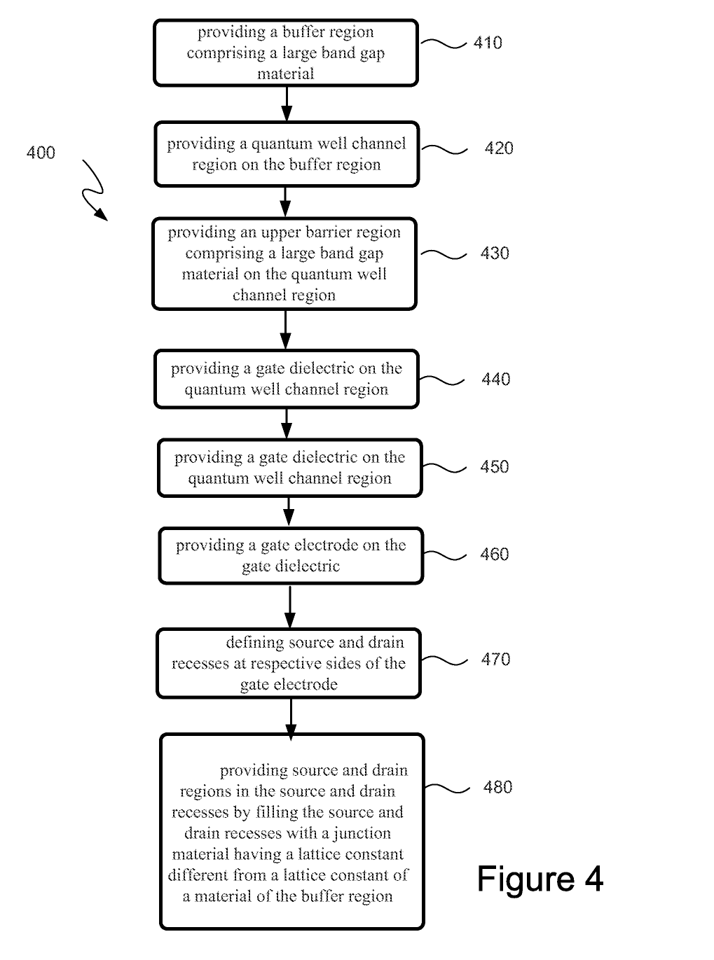

Referring next to FIG. 4, a method embodiment 400 is depicted. As shown in FIG. 4, method 400 includes at block 410 providing a buffer region comprising a large band gap material, at block 420 providing a quantum well channel region on the buffer region, at block 430 providing an upper barrier region comprising a large band gap material on the quantum well channel region, at block 440 providing an upper barrier region comprising a large band gap material on the quantum well channel region, at block 450 providing a gate dielectric on the quantum well channel region, at block 460 providing a gate electrode on the gate dielectric, at block 470 defining source and drain recesses at respective sides of the gate electrode, and at block 480 providing source and drain regions in the source and drain recesses by filling the source and drain recesses with a junction material ##.

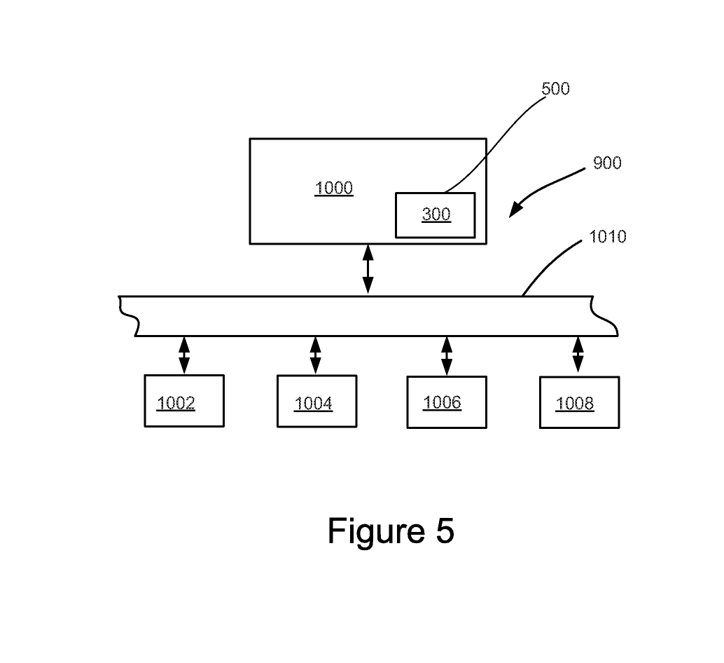

Referring to FIG. 5, there is illustrated one of many possible systems 500 in which embodiments of the present invention may be used. In one embodiment, the electronic arrangement 1000 may include an integrated circuit 510 including a CMOS device such as device 300 of FIG. 3. The device 300 may be part of a device layer of integrated circuit 510. The integrated circuit 510 may further include a plurality of inter-layer dielectric layers disposed on the device layer; and a plurality of metal lines interleaved between the inter-layer dielectric layers in a well-known manner. Arrangement 1000 may further include a microprocessor. In an alternate embodiment, the electronic arrangement 1000 may include an application specific IC (ASIC). Integrated circuits found in chipsets (e.g., graphics, sound, and control chipsets) may also be packaged in accordance with embodiments of this invention.

For the embodiment depicted by FIG. 5, the system 500 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 500 may be a wireless mobile phone, a personal digital assistant, a pocket PC, a tablet PC, a notebook PC, a desktop computer, a set-top box, a media-center PC, a DVD player, and a server.

In the foregoing specification, specific embodiments are described. However, various modifications and changes may be made thereto without departing from the broader spirit and scope of embodiments as set forth in the claims. The specification and drawings are, accordingly, to be regarded in an illustrative rather than a restrictive sense.

What is claimed is:

1. A device, comprising:
a buffer region comprising a large band gap material;
a uniaxially strained quantum well channel region on the buffer region;
an upper barrier region comprising a large band gap material on the quantum well channel region;
a gate dielectric on the quantum well channel region;
a gate electrode on the gate dielectric;
recessed source and drain regions at respective sides of the gate electrode, the source and drain regions including a junction material having a lattice constant different from a lattice constant of a material of the buffer region.

2. The device of claim 1, wherein the buffer region comprises silicon germanium.

3. The device of claim 2, wherein the silicon germanium comprises a Si₁₋ₓGeₓ material, and the junction material comprises Si_{1-y}Ge_{y} material where y is different from x.

4. The device of claim 2, wherein the junction material comprises silicon germanium having a higher concentration of germanium than a silicon germanium of the buffer region.

5. The device of claim 1, wherein the junction material comprises one of silicon germanium, pure germanium and tin germanium.

6. The device of claim 1, wherein the junction material is doped.

7. The device of claim 1, wherein the recessed source and drain regions extend below a bottom surface of the gate electrode to a recess depth between about 300 and about 400 Angstroms.

8. The device of claim 1, wherein the source and drain regions are raised source and drain regions.

9. The device of claim 8, wherein the recessed source and drain regions extend above a top surface of the quantum well region to a height of about 400 Angstroms.

10. The device of claim 1, wherein each of the upper barrier region and the buffer region have a lattice spacing different from a lattice spacing of the channel region.

11. The device of claim 1, wherein the upper barrier region comprises silicon germanium.

12. The device of claim 1, wherein the buffer region is directly below the quantum well channel region.

13. The device of claim 1, wherein the barrier region is directly above the quantum well channel region.

14. The device of claim 1, wherein the source and drain regions are epitaxially grown regions.

15. A method comprising:
providing a buffer region comprising a large band gap material;
providing a quantum well channel region on the buffer region;
providing an upper barrier region comprising a large band gap material on the quantum well channel region;
providing a gate dielectric on the quantum well channel region;
providing a gate electrode on the gate dielectric;
defining source and drain recesses at respective sides of the gate electrode;
providing source and drain regions in the source and drain recesses by filling the source and drain recesses with a junction material having a lattice constant different from a lattice constant of a material of the buffer region.

16. The method of claim 15, wherein the buffer region comprises silicon germanium.

17. The method of claim 16, wherein the silicon germanium comprises a Si₁₋ₓ Geₓ material, and the junction material comprises Si_{1-y}Ge_{y} material where y is different from x.

18. The method of claim 16, wherein the junction material comprises silicon germanium having a higher concentration of germanium than a silicon germanium of the buffer region.

19. The method of claim 15, wherein the junction material comprises one of silicon germanium, pure germanium and tin germanium.

20. The method of claim 15, further comprising doping the junction material.

21. The method of claim 15, wherein the recessed source and drain regions extend below a bottom surface of the gate electrode to a recess depth between about 300 and about 400 Angstroms.

22. The method of claim 15, wherein the recessed source and drain regions extend above a bottom surface of the gate electrode to a height of about 400 Angstroms.

23. The method of claim 15, wherein each of the upper barrier region and the buffer region have a lattice spacing different from a lattice spacing of the channel region.

24. The method of claim 15, wherein filling the source and drain recesses comprises epitaxially growing the junction material in the source and drain recesses.

26. The method of claim 15, wherein defining source and drain recesses comprises etching the recesses using a wet etch.

27. The method of claim 26, wherein defining the source and drain recesses comprises etching the recesses using a dry etch followed by the wet etch.

28. The method of claim 15, wherein providing source and drain regions further comprises thermally treating the junction material after filling.

29. A system comprising:
an integrated circuit comprising:
a device layer comprising a plurality of devices, the devices including at least one device comprising:
a buffer region comprising a large band gap material;
a uniaxially strained quantum well channel region on the buffer region;
an upper barrier region comprising a large band gap material on the quantum well channel region;
a gate dielectric on the quantum well channel region;
a gate electrode on the gate dielectric;
recessed source and drain regions at respective sides of the gate electrode, the source and drain regions including a junction material having a lattice constant different from a lattice constant of a material of the buffer region;
a plurality of inter-layer dielectric layers disposed on the device layer;
a plurality of metal lines interleaved between the inter-layer dielectric layers; and
a graphics processor coupled to the integrated circuit.

30. The system of claim 29, wherein the silicon germanium comprises a Si₁₋ₓ Geₓ material, and the junction material comprises Si_{1-y}Ge_{y} material where y is different from x.
